(19) United States
(12) Patent Application Publication
(10) Pub. No.: US 2013/0299950 A1
(43) Pub. Date: Nov. 14, 2013

(54) SEMICONDUCTOR STRUCTURE WITH BURIED THROUGH SUBSTRATE VIAS

(71) Applicant: Klaus HUMMLER, Ballston Lake, NY (US)

(72) Inventor: Klaus HUMMLER, Ballston Lake, NY (US)

(73) Assignee: SEMATECH, INC., Albany, NY (US)

(21) Appl. No.: 13/469,494

(22) Filed: May 11, 2012

(51) Int. Cl. H01L 23/34; H01L 21/30; H01L 21/20

(52) U.S. Cl. 257/622; 438/481; 438/459; 257/E23.08; 257/E21.09; 257/E21.211

(57) ABSTRACT

Semiconductor structures and methods of fabrication are provided. One semiconductor structure includes a substrate, a semiconductor device layer supported by the substrate, and one or more buried through substrate vias (TSVs) disposed at least partially within the substrate. The buried through substrate via(s) is buried within the semiconductor substrate, and terminates below the semiconductor device layer of the semiconductor structure, and the semiconductor device layer extends over the buried through substrate via(s), thereby providing the buried through substrate via(s) without consuming space within the semiconductor device layer. A dielectric layer may be disposed between the substrate and the semiconductor device layer, with the TSV(s) terminating at a first end within the dielectric layer. Alternatively, the semiconductor device layer may be an epitaxially-grown layer extending over the TSV(s). Where a plurality of buried TSV(s) are employed, the vias may be disposed in a repeating pattern across the semiconductor structure.

### BACKGROUND

This invention relates generally to semiconductor or other electrical device fabrication, and more particularly, to fabrication of structures with through substrate vias, including semiconductor structures with through substrate vias, and other electrical devices, such as microelectromechanical systems (MEMS), manufactured on a substrate with through substrate vias.

As semiconductor scaling faces difficulty at device dimensions approaching atomic scale, three-dimensional device integration offers a method for increasing density of semiconductor devices within a device. In three-dimensional integration, a plurality of semiconductor die or chips may be vertically stacked with electrical contacts disposed on both the active surfaces and the back surfaces of the chips so as to increase electrical interconnections between the stacked chips.

Through substrate vias (TSVs) (or through silicon vias) facilitate, at least in part, this electrical interconnection. Conventionally, a through substrate via extends from the active surface or side (for example, from a line-level metal wiring structure on the front surface, which is typically a first metal wiring level in a metal interconnect structure) to the back surface or side of the semiconductor die or chip. These through substrate vias provide electrical connection paths through the substrate of the semiconductor chip, for example, to facilitate electrically interconnecting a plurality of stacked semiconductor chips.

### BRIEF SUMMARY

In one aspect, provided herein is a semiconductor structure which comprises a substrate, a semiconductor device layer supported by the substrate, and at least one buried through substrate via. The at least one buried through substrate via is disposed at least partially within the substrate and buried within the semiconductor structure. The at least one buried through substrate via terminates below the semiconductor device layer of the semiconductor structure, wherein the semiconductor device layer extends over the at least one buried through substrate via.

In another aspect, a method is presented which includes providing at least one semiconductor structure comprising at least one buried through substrate via (TSV) within the semiconductor structure. The providing includes: providing a substrate; providing at least one buried through substrate via at least partially within the substrate; and providing a semiconductor device layer over the at least one buried through substrate via, wherein the at least one buried through substrate via terminates below the semiconductor device layer of the semiconductor structure, and wherein the semiconductor device layer extends over the at least one buried through substrate via.

In a further aspect, a method is provided which includes providing a wafer comprising at least one buried through substrate via (TSV). The providing includes: providing a first semiconductor structure comprising a first substrate with a first dielectric layer over the first substrate, and at least one buried through substrate via extending into the first substrate; providing a second semiconductor structure comprising a second substrate and a second dielectric layer disposed over the second substrate; stacking the second semiconductor structure on the first semiconductor structure and securing the first dielectric layer and the second dielectric layer together; and thinning the second substrate of the second semiconductor structure to provide a semiconductor device layer of the wafer, wherein the at least one buried through substrate via terminates below the semiconductor device layer, and the semiconductor device layer extends over the at least one buried through substrate via.

In a still further aspect, a method is provided which includes providing a wafer comprising at least one buried through substrate via (TSV). The providing includes: obtaining a substrate; providing at least one through substrate via within the substrate; and burying the at least one through substrate via within the substrate to define the at least one buried through substrate via, the burying comprising epitaxially growing a layer to extend over the at least one through substrate via.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a process for providing one or more through substrate vias (TSVs) through a substrate, in accordance with one or more aspects of the present invention;

FIG. 2A depicts (by way of example only) a partial cross-sectional elevational view of a front-side of a semiconductor structure comprising a wafer with a patterned mask opening in a shallow trench isolation region, to facilitate through substrate via formation, in accordance with one or more aspects of the present invention;

FIG. 2B depicts the semiconductor structure of FIG. 2A, after formation of a recess in the front-side of the wafer, in accordance with one or more aspects of the present invention;

FIG. 2C depicts the semiconductor structure of FIG. 2B, after providing a dielectric liner and filling, at least partially, the recess with a sacrificial material, in accordance with one or more aspects of the present invention;

FIG. 2D depicts the semiconductor structure of FIG. 2C, after etching back the sacrificial material on the front-side of the wafer, and removing remnants of the hard mask employed in forming the recess, in accordance with one or more aspects of the present invention;

FIG. 2E depicts the semiconductor structure of FIG. 2D, after mid-of-the-line (MOL) processing to form (at the front-side) electrical contacts to a silicide layer in the sacrificial material disposed within the recess, in accordance with one or more aspects of the present invention;

FIG. 2F depicts the semiconductor structure of FIG. 2E, after back-side thinning of the wafer to reveal the recess at least partially filled with the sacrificial material, in accordance with one or more aspects of the present invention;

FIG. 2G depicts the semiconductor structure of FIG. 2F, after performing back-side processing, including dielectric deposition and opening of the through substrate via at the back-side of the wafer, in accordance with one or more aspects of the present invention;

FIG. 2H depicts the semiconductor structure of FIG. 2G, after further optional back-side processing, to facilitate an RDL damascene process, in accordance with one or more aspects of the present invention;

FIG. 2I depicts the semiconductor structure of FIG. 2H, after removing from the back-side of the wafer the sacrificial material from the recess, in accordance with one or more aspects of the present invention;

FIG. 2J depicts the semiconductor structure of FIG. 2I, after depositing a barrier layer, and filling the recess from the back-side of the wafer with a conductive material, to provide the through substrate via concurrent with, in the example depicted, formation of a back-side, line-level metallization, in accordance with one or more aspects of the present invention;

FIG. 3A depicts (by way of example only) a partial cross-sectional elevational view of a semiconductor structure (such as a wafer) with a dielectric layer at a front side thereof, in accordance with one or more aspects of the present invention;

FIG. 3B depicts a first semiconductor structure obtained from the semiconductor structure of FIG. 3A, after undergoing n-type implantation to define, by way of example, an activated n-type layer in the substrate, in accordance with one or more aspects of the present invention;

FIG. 3C depicts a second semiconductor structure obtained from the semiconductor structure of FIG. 3A, after forming of one or more buried through substrate vias therein extending, by way of example, from the front side of the semiconductor structure through the dielectric layer and into the substrate, in accordance with one or more aspects of the present invention;

FIG. 3D depicts a semiconductor structure formed by stacking the first semiconductor structure of FIG. 3B and second semiconductor structure of FIG. 3C, with the first semiconductor structure inverted, and the dielectric layers of the first and second semiconductor structure bonded together, in accordance with one or more aspects of the present invention;

FIG. 3E depicts the semiconductor structure of FIG. 3D, after partial removal of semiconductor material from the front side of the semiconductor structure to provide a semiconductor device layer of the semiconductor structure, in accordance with one or more aspects of the present invention;

FIG. 4A depicts a partial cross-sectional elevational view of another embodiment of a front side of a semiconductor structure (such as a wafer) with one or more through substrate vias provided therein extending, by way of example, from the front side of the semiconductor structure into the substrate, in accordance with one or more aspects of the present invention;

FIG. 4B depicts the semiconductor structure of FIG. 4A after providing, for example, by epitaxial growth, a semiconductor device layer over the one or more through substrate vias of the semiconductor structure to form one or more buried through substrate vias, in accordance with one or more aspects of the present invention;

FIG. 5A depicts (by way of example only) a partial cross-sectional elevational view of a semiconductor structure comprising one or more buried through substrate vias electrically contacted by one or more contact vias of or extending through the semiconductor device layer, in accordance with one or more aspects of the present invention;

FIG. 5B depicts (by way of example only) a partial cross-sectional elevational view of an alternate embodiment of a semiconductor structure comprising one or more buried through substrate vias disposed below a semiconductor device layer of the semiconductor structure, and configured and positioned to facilitate heat removal from a designated region of the semiconductor device layer or heat redistribution within the semiconductor structure, in accordance with one or more aspects of the present invention;

FIG. 5C depicts (by way of example only) a partial cross-sectional elevational view of another embodiment of a semiconductor structure comprising one or more buried through substrate vias disposed below a semiconductor device layer of the semiconductor structure, and configured and positioned to capacitively couple to the semiconductor device layer, in accordance with one or more aspects of the present invention; and

FIG. 6 depicts one embodiment of a flow diagram of a design process which may be employed in semiconductor design and manufacture of semiconductor structures, in accordance with one or more aspects of the present invention.

### DETAILED DESCRIPTION

Generally stated, disclosed herein are various enhancements to through substrate vias (TSVs) (or through silicon vias) for semiconductor structures. These enhancements include new TSV formation approaches, and new, buried TSV structures (and fabrication approaches therefor). Note, that as used herein, “semiconductor structure” may comprise a wafer for which active devices and/or interconnect layers are yet to be formed, or may refer to a completed structure with active devices and/or interconnect layers defined. The through substrate via (TSV) is characterized, in one embodiment, as extending substantially through the substrate of the completed device, for example, with the wafer substrate thinned to expose the TSV at a back side of the wafer or chip.

Note that reference is made below to the drawings, which are not drawn to scale to facilitate an understanding of the invention, wherein the same reference numbers used throughout different figures designate the same or similar components.

As noted, three-dimensional circuit integration using through substrate vias is an emerging technology which will result in performance, power and reliability enhancements, and ultimately, cost benefits, compared with traditional, two-dimensional integration or other forms of three-dimensional integration. A variety of approaches may be employed in integrating TSVs into semiconductor device fabrication and packaging flows. These include:
TSV-first: In this approach, TSVs are processed and filled with electrically-conducting material from the wafer front-side before active device processing, and the TSVs are later revealed by thinning and electrically contacting from the wafer back-side.
TSV-mid: In this approach, TSVs are processed and filled with electrically-conducting material from the wafer front-side after mid-of-the-line (MOL) contact-level processing, and before or at any level during back-end-of-line (BEOL) processing (such as at, for example, metal-level 5 of a 9 BEOL metal-level structure). The TSVs are later revealed by thinning and electrically contacting from the wafer back-side.
TSV-last: In this approach, TSVs are processed and filled with electrically-conducting material from the wafer front-side after BEOL processing is completed. The TSVs are revealed by electrically thinning and electrically contacting from the wafer back-side.
TSV-last—back-side: In this approach, TSVs are processed and filled with electrically-conducting material from the wafer back-side, after BEOL processing over the front-side, and wafer thinning.

Each of the above-noted approaches has unique advantages and disadvantages, with the largest differences being found between the TSV-first and the remaining integration approaches. In the TSV-first approach, because it is first in the processing flow, high-temperature processes can be used to form the TSV. This relates especially to the dielectric, where thermal oxide may be employed. However, with this approach, the conductive TSV fill is subjected to and present during all subsequent, active device processing, and therefore, copper does not work well for the TSV fill because of the subsequent high-temperature process steps, thermal expansion, stress and contamination concerns that may arise with such a structure during active device processing. Alternative fills, such as tungsten or polysilicon, exhibit significantly higher resistance than low-resistance conductive materials, such as copper, and may still lead to contamination and stress issues during the active device processing steps.

Contrasted with this, the TSV-mid, TSV-last, and TSV-last—back-side approaches allow copper as the electrically conductive fill since there are limited process temperatures after TSV formation using these approaches. However, the dielectric and other TSV processes are limited in temperature and overall thermal budget, due to the potential negative effects on the existing active devices, such as transistor characteristics. In addition, TSV lithography, etching and filling are disruptive to MOL/BEOL structures, and potentially damaging the to the structures. In the case of TSV-mid, and TSV-last, etching through the MOL/BEOL stack might cause undercut and other sidewall issues. In the case of TSV-last—back-side, etch stop and dielectric liner open are very challenging unit processes.

As noted, disclosed herein, in one aspect, is a new TSV formation approach, which may be characterized as TSV-first-and-last. This formation approach provides a novel integration flow which combines the major advantages of the various above-noted TSV process flows, without creating any significant disadvantages.

One or more through substrate vias (TSVs) through a substrate or wafer are provided herein by: forming at least one recess in a first side of a wafer, filling, at least partially, the at least one recess with a sacrificial material from the first side of the wafer; thinning the wafer from a second side to reveal the at least one recess at least partially filled with the sacrificial material; removing from the second side of the wafer, the sacrificial material from the at least one recess; and filling the at least one recess from the second side of the wafer with a conductive material to provide the at least one through substrate via. In the examples described below, the first side is a front-side (or surface) of the wafer, and the second side is a back-side (or surface) of the wafer, wherein the front-side is an active device side of the wafer. Further, the recess formation and filling thereof with the sacrificial material are performed before active device (e.g., transistor) processing, and the removing and the filling with the conductive material are performed after the active device processing. As an optional enhancement, filling, at least partially, the recess with the sacrificial material, may include filling the recess(es) with the sacrificial material so as to create one or more fill voids (for example, one or more unexposed voids within the sacrificial material), which subsequently facilitate fast removal of the sacrificial material from the recess from the back-side of the wafer, as described herein. Advantageously, TSV contacting is from the front side, using (for example) standard MOL contacts to diffusion, and if desired, dual damascene processing may be employed to create the conductive TSV(s) along with a first-level, back-side metallization.

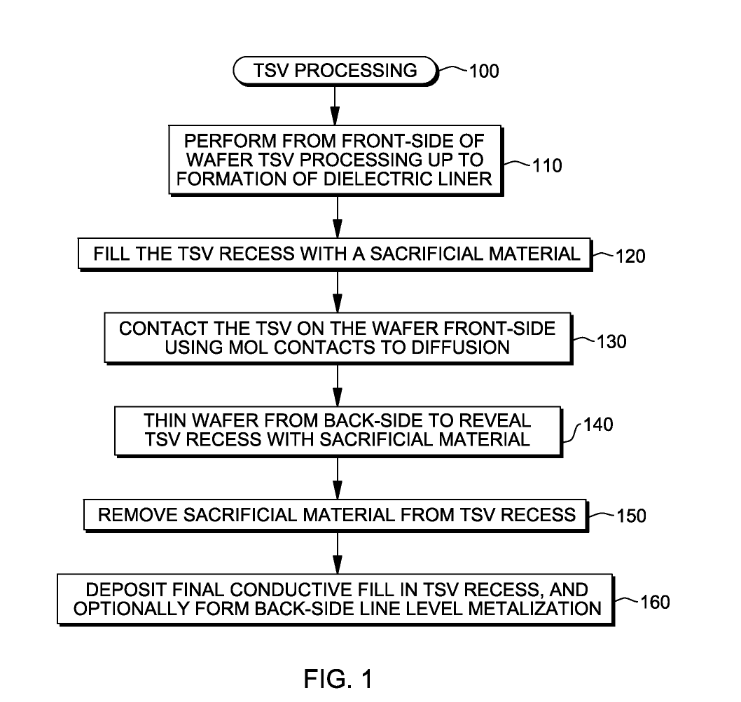

More particularly, and referring to the TSV processing 100 of FIG. 1, through substrate vias may be fabricated, in accordance with one or more aspects of the present invention, by performing TSV processing up to the formation of the dielectric liner within the recesses, before active device (e.g., transistor) processing 110. This TSV processing is from the front-side of the wafer, and allows for ready processing on a pristine wafer, as well as high-temperature recipes for the formation of the dielectric liner. This also results in cost savings because, in one embodiment, this front-side processing may be integrated with the shallow-trench isolation (STI) process module, to have more synergies than were it integrated with MOL or BEOL processing modules, as in certain of the above-described TSV approaches.

Next, the TSV recesses are filled with a sacrificial material 120. This material can be chosen to be a low-stress material, and have a low-cost of ownership, etc. One possible choice is polysilicon, but other materials could also be employed. By filling the TSV recesses with polysilicon, standard transistor, MOL and BEOL processings may be subsequently employed, without the risk of excessive stress or contamination through the TSV recesses. Note that any cost increase due to the sacrificial fill and its removal are readily compensated by cost reductions achieved in other process areas employing the TSV formation approach disclosed herein.

Contacts to the TSV recesses with sacrificial material may be made on the wafer front-side using standard MOL contacts to diffusion (CA) 130. This will lead to cost reduction in comparison with other TSV approaches, since the MOL process is not disrupted in any way. Forming the TSV recesses with sacrificial material at substrate level, and contacting the TSV recesses with sacrificial material with MOL contacts to diffusion frees design space on the first metallization layer (M1), as well as higher BEOL levels, which can result in a significant increase in available routing space, that is, where through substrate vias are employed.

The wafer is then thinned 140, revealing the TSV recesses with sacrificial material, and the sacrificial material is removed 150, and the final, low-resistance conductive fill is deposited 160. In one embodiment, this conductive fill may comprise copper. Advantageously, because of the use of a benign, temporary TSV recess fill material, there is no risk of wafer contamination during thinning and TSV reveal processes. In contrast to a “TSV-last—back-side” approach, there is also no need to stop a deep silicon reactive ion etch process on a front-side metal, or to open the dielectric liner deep inside the TSV recess. Since the contact to the front side is ready for conductive material deposition after the sacrificial fill is stripped, a dual damascene process, together with a back-side, line-level metallization can be realized, which can result in additional cost savings. Note also that, if desired, after the sacrificial material has been removed, the TSV side wall could be lined with a conductive material rather than completely filling the recess, which would provide sufficient electrical conductivity, but reduce thermo-mechanical stress. Such a partial fill of the TSV recess is not easy with the TSV approaches summarized above (except for TSV-last—back-side) because they all require planarization steps which do not work with a hole in the center of the TSV (i.e., the so-called “annular” TSV).

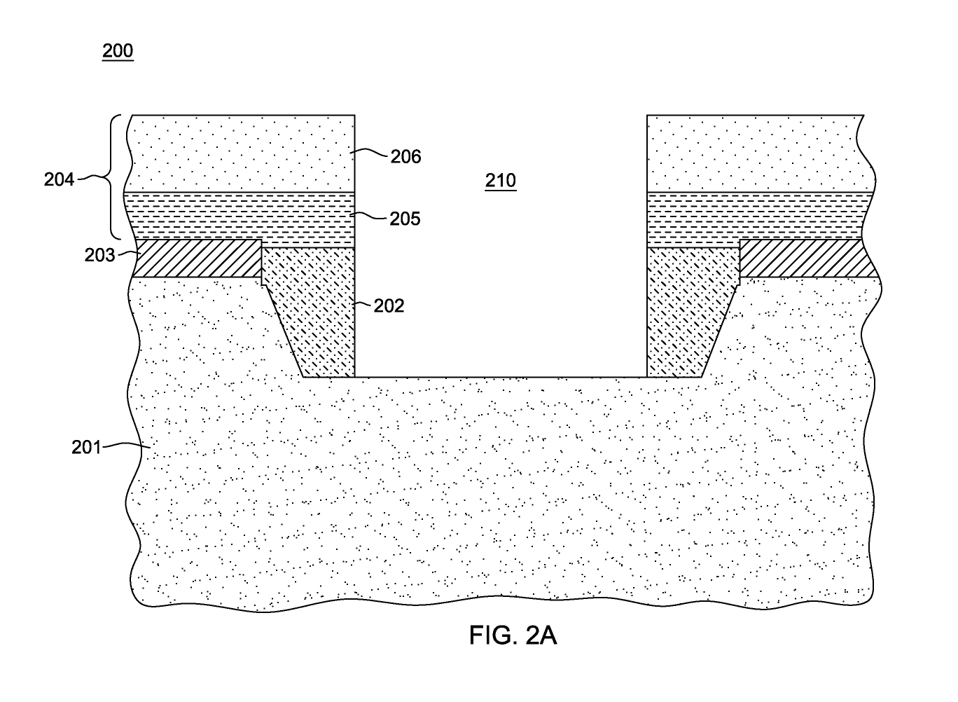

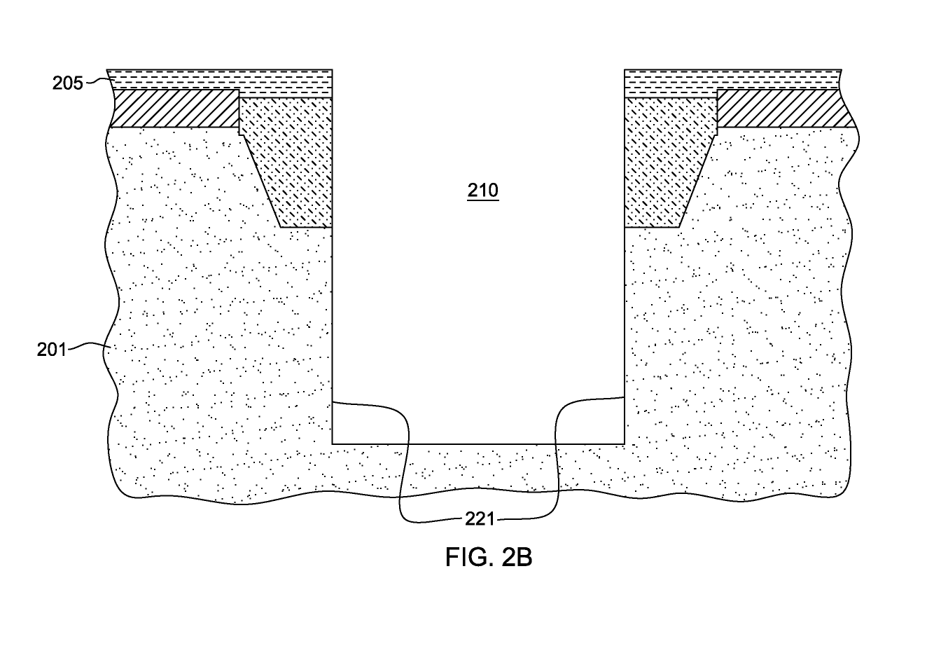

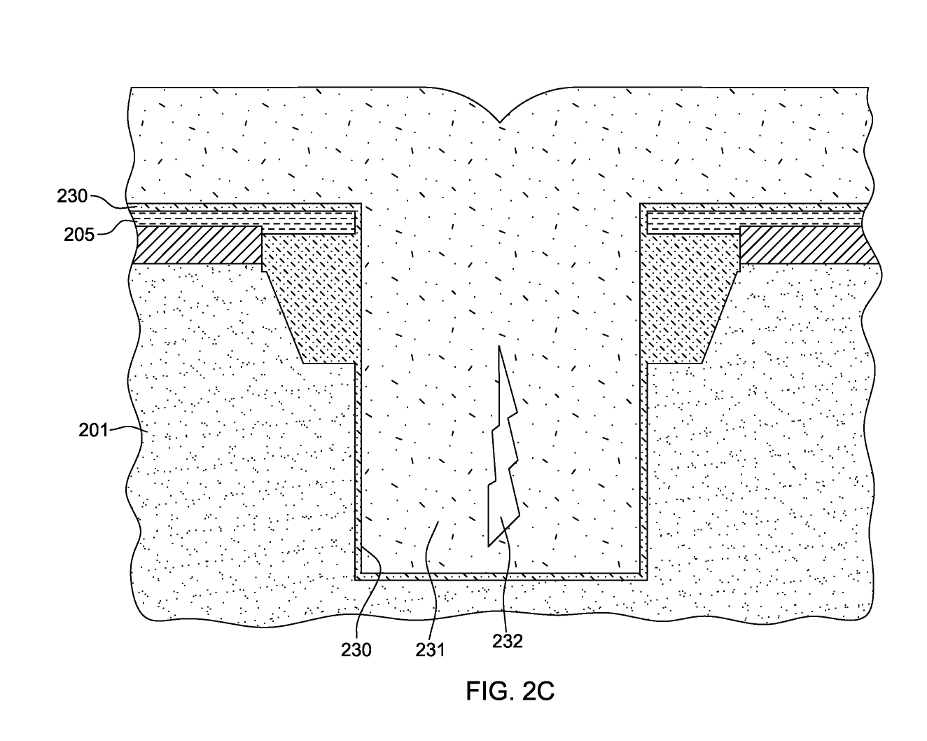

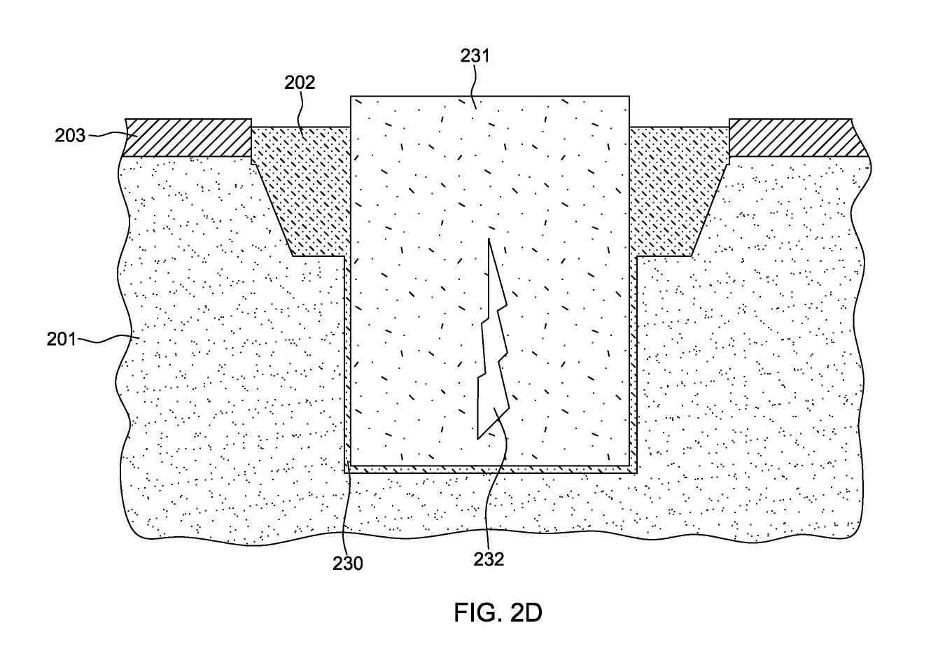

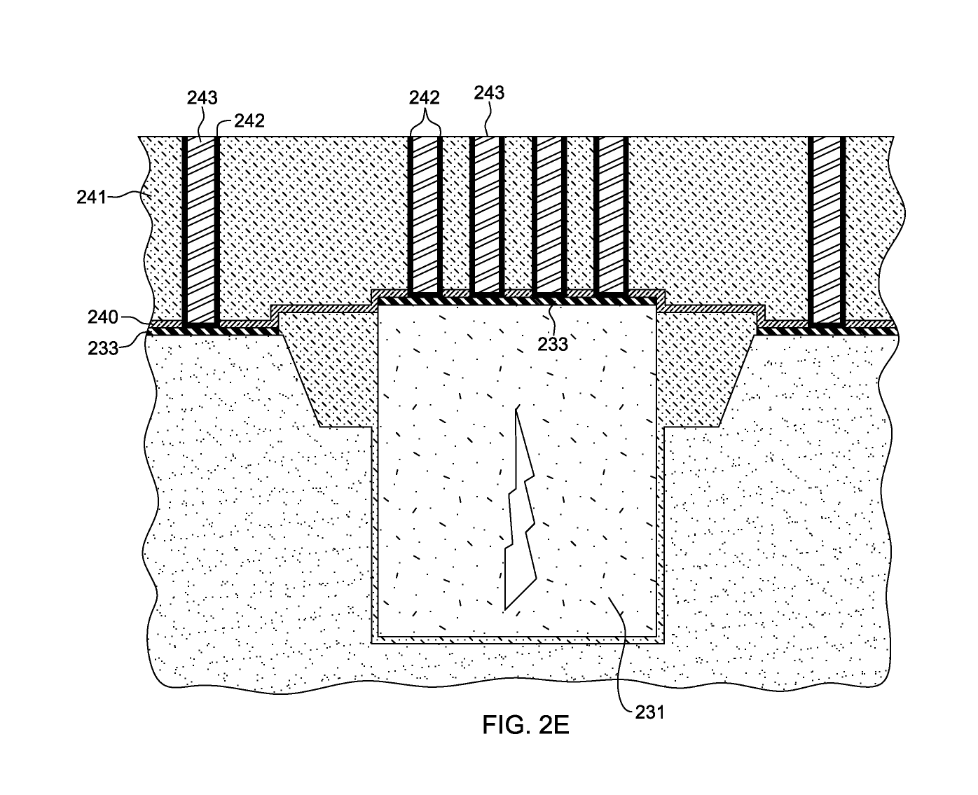

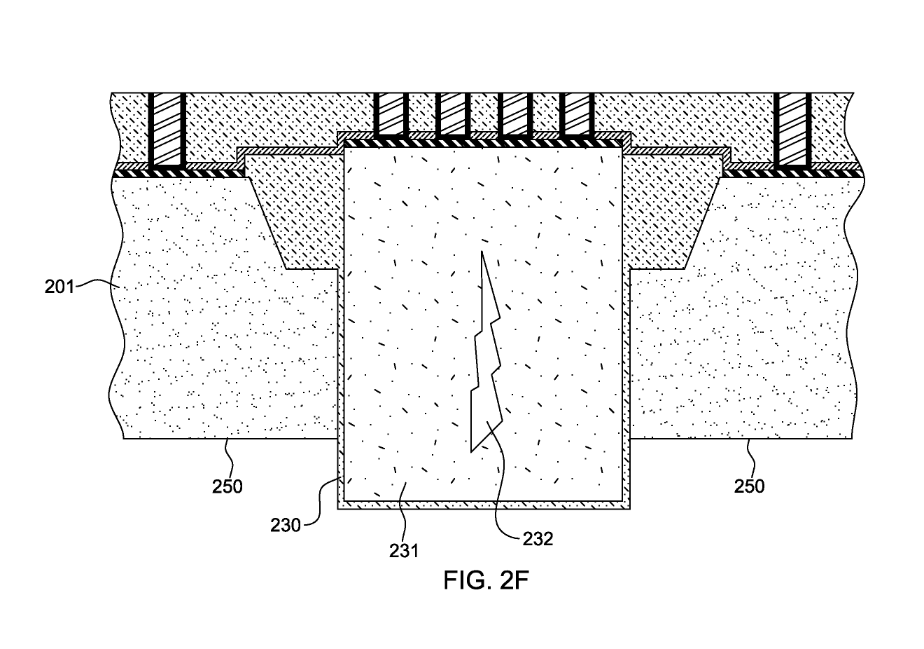

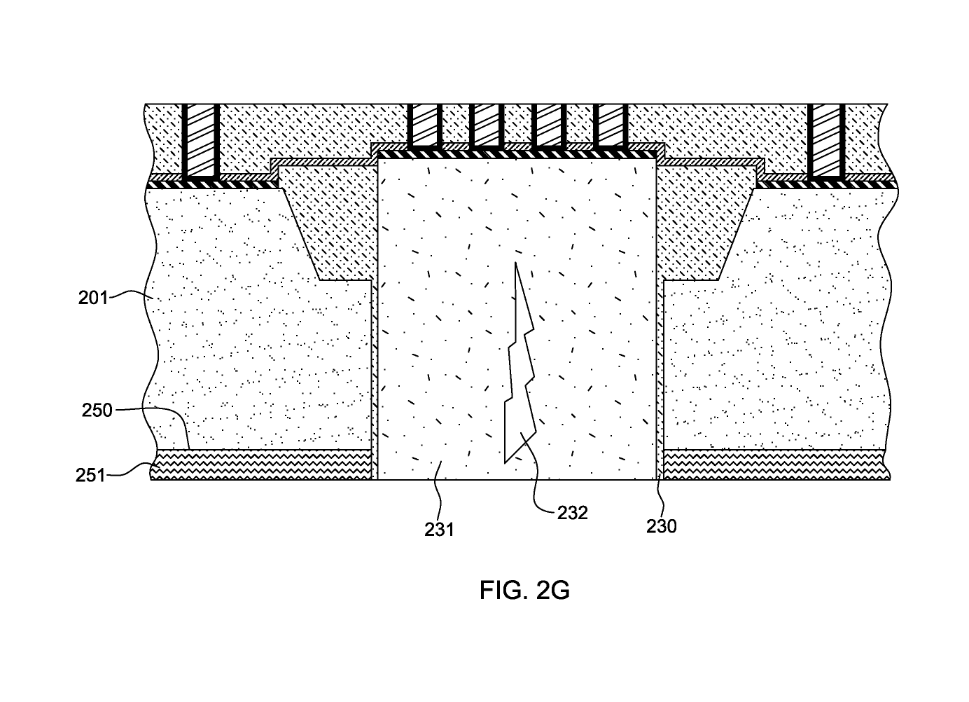

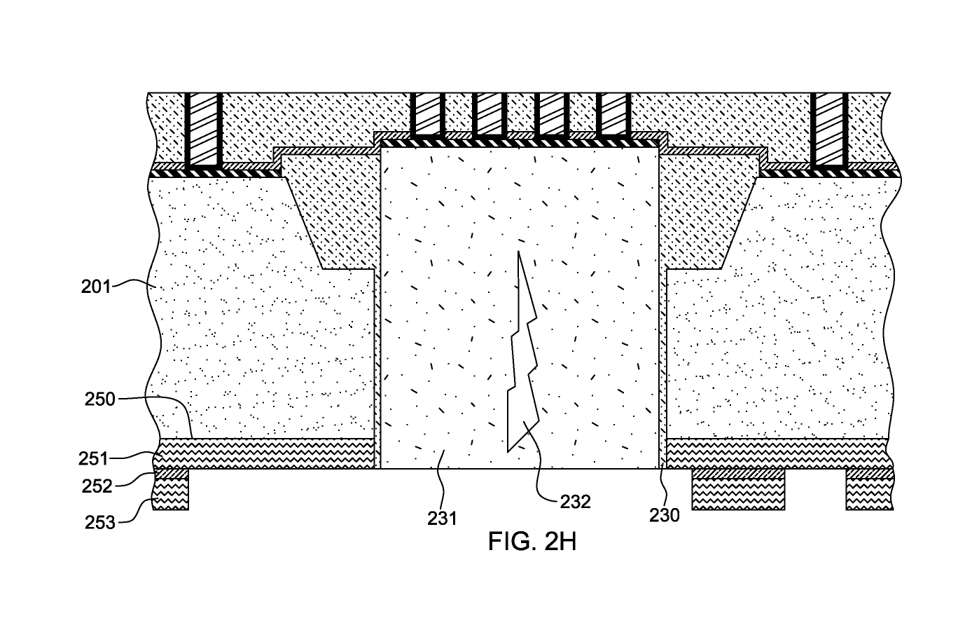

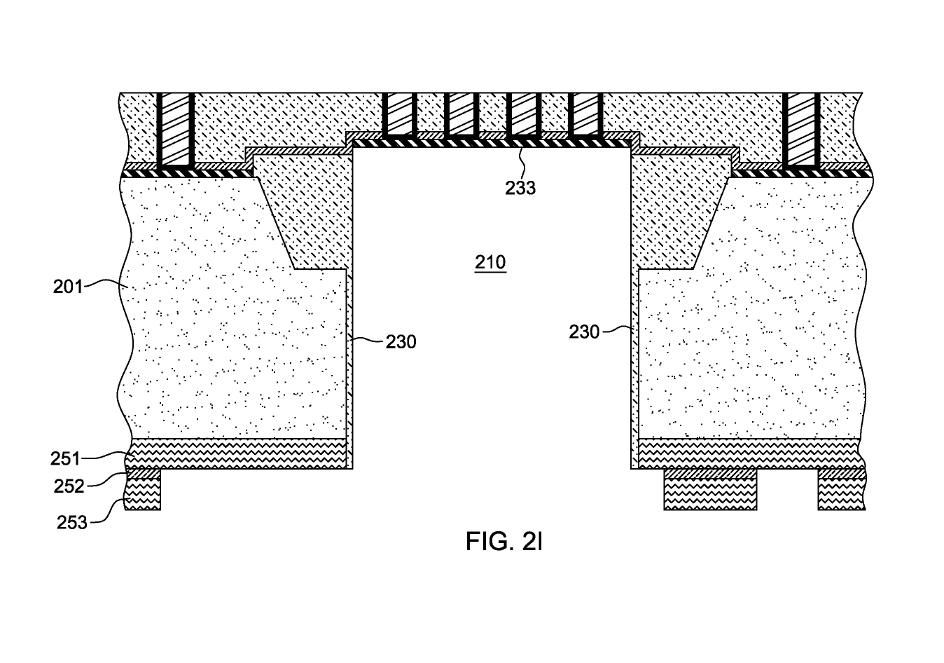

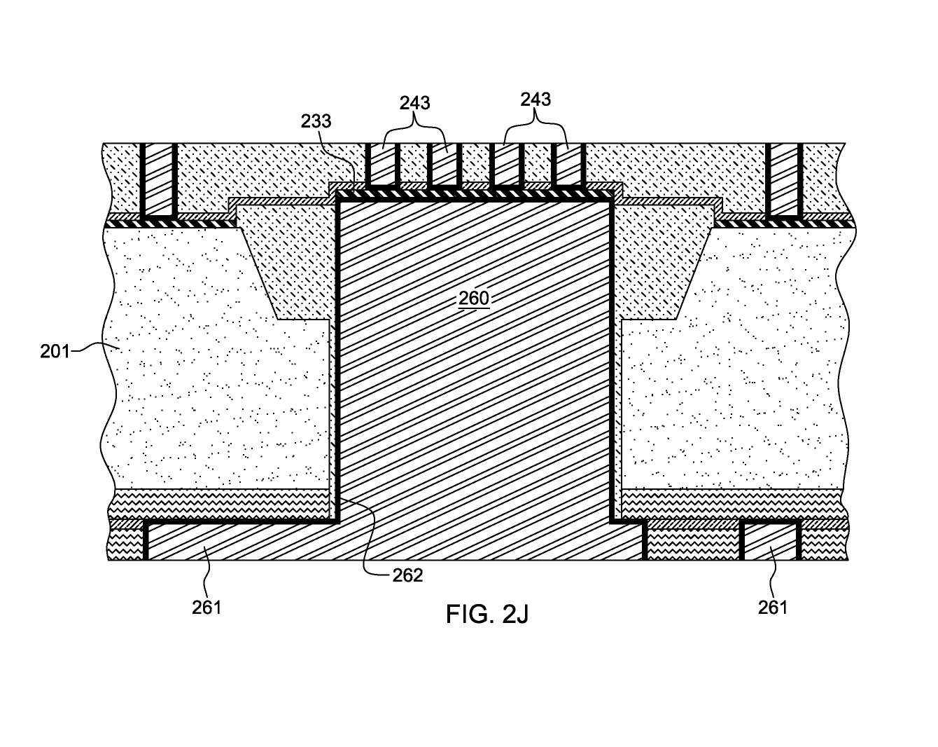

FIGS. 2A-2J depict, by way of example only, one detailed process embodiment for TSV formation, in accordance with one or more aspects of the present invention. Those skilled in the art will note that the concepts disclosed herein can be readily adapted to other process flows than that depicted in FIGS. 2A-2J. For example, the initial etching steps of FIGS. 2A & 2B could be performed earlier or later in the semiconductor device fabrication process.

FIG. 2A illustrates one embodiment of a semiconductor structure 200 comprising a substrate (or wafer) 201 (e.g., a silicon wafer) having undergone shallow trench isolation processing at the front-side of the wafer, resulting in the formation of one or more STI-oxide trenches 202, and one or more silicon nitride (SiN) pad(s) 203 at the front surface of wafer 201. After completion of (or integrated with) the STI process module, TSV lithography and mask opening is performed. Specifically, in the depicted example, after completion of STI formation, a mask 204 comprising, in one example, a TSV TEOS hard mask 205, and a TSV resist 206, is deposited, and patterned by lithography. Note that in an alternate embodiment, rather than employing a TEOS hard mask, a thicker resist could be employed as the mask. This thicker resist might be 1-2 microns thick, or greater, depending upon the depth of the TSV to be formed. The hard mask and STI are then etched, in one embodiment, in one step to form a recess or opening 210 through the mask and STI. The hard mask etch (or STI etch in the case of thick resist) stops on the silicon wafer 201, as illustrated in FIG. 2A. Note that, in one embodiment, these initial TSV process steps occur prior to formation of the active devices at, for example, the front-side of the wafer.

Referring to FIG. 2B, a deep silicon RIE or BOSCH etch is performed to form the TSV recess 210 extending into silicon wafer 201. Note that the resultant profile comprises vertical side walls 221 or side walls with a slightly, re-entrant profile (not shown) to facilitate conductive fill from the wafer back-side. Note in this regard, that the subsequent dielectric and temporary fill processes are able to accommodate a re-entrant profile. The resist 205 is then stripped after the hard mask etch or after the silicon RIE (in the case of a thick resist).

FIG. 2C illustrates the semiconductor structure of FIG. 2B, after a dielectric liner 230 has been formed, for example, by thermal oxide or oxy-nitride formation and/or CVD. if desired, a non-conformal oxide deposition could be added to create a re-entrant TSV profile (not shown) for easier conductive fill from the back-side of wafer 201. The TSV recess is then at least partially filled with a sacrificial material 231, which in one example, might comprise CVD polysilicon. The deposition process could intentionally be non-conformal to pinch off the sacrificial material at the top of the TSV recess, and create one or more center-disposed, fill voids 232 within the TSV-filled recess. These fill voids will facilitate faster removal of the sacrificial material from the recesses subsequently in the process flow. The fill process can be controlled so that the position of the void(s) can be engineered such that no fill void is present at the top STI level on the front-side of the wafer.

As illustrated in FIG. 2D, through CMP and/or etch-back, the sacrificial material 231 (e.g., polysilicon) and dielectric liner 230, as well as any optional hard mask 205 (see FIG. 2C) are planarized back to the pad SiN 203. The device fabrication process then continues, with typical post-STI FEOL, MOL and BEOL process flows.

In the example depicted in FIG. 2E, a silicide layer 233 has been formed within the sacrificial material, and selectively at the front surface of the silicon wafer 201, to improve electrical contacts where desired. This silicide layer may comprise, for example, cobalt silicide or nickel silicide. A barrier layer 240 is introduced to contain any contaminants in the BEOL from reaching the silicon wafer and destroying any active devices formed within the wafer. The electrical contacts comprise a conductive barrier layer 242 and conductive contacts 243, which may comprise, in one example, copper. Advantageously, in accordance with this aspect of Applicants' invention, the diffusion contacts can land on the sacrificial material, filling the TSV recess, and in one example, electrically contact the silicide layer 233 within the TSV recess formed at the front-side of the wafer. This process step results in freeing design space on the front-side metal one level that would otherwise be needed to electrically contact through to the TSV using the above-described TSV formation approaches. In accordance with the process steps disclosed herein, there is no breech to the mid-end-of-line (MOL) layer.

After active device formation, and typical FEOL, MOL and BEOL process flows, processing continues with TSV wafer thinning and a back-side reveal process, to (in one example) obtain the semiconductor structure depicted in FIG. 2F. In this process flow, the wafer may be flipped and temporarily bonded to a carrier for thinning close to the TSV recess, with the final TSV reveal being by silicon wet or dry etching selective to the TSV dielectric 230. Thinnig close to the TSV recess could be performed by course-grinding, then fine-grinding the back-side of the wafer close to the bottom of the TSV recess. By way of example, a 650-700 micron wafer may be thinned to approximately 50 microns.

As illustrated in FIG. 2G, a planarizing oxide deposition 251 is performed over the back surface 250 of wafer 201 and CMP processing at the back-side of the wafer opens the TSV recess to reveal sacrificial material 231. Note that enough of the TSV recess should be polished away to ensure a non-re-entrant profile for the conductive fill.

Optionally, at this point in the process, back-side isolation structure processing could be performed to prepare for dual damascene formation of the back-side metallization and the TSV conductive material fill. As illustrated in FIG. 2H, these layers may include a stop layer 252 and an inter-layer dielectric (ILD) deposition 253, along with patterning and etching of the ILD and stop layer, to achieve the desired, back-side metallization mask. Note the use of dual damascene processing in forming the through substrate vias, is an advantage of the first-and-last approach described herein over those TSV approaches initially discussed.

As illustrated in FIG. 2I, the sacrificial material (e.g., polysilicon) is removed by a wet or isotropic dry etch, exposing TSV recess 210 from the back-side of the wafer. As noted, one or more fill voids in the sacrificial material within the TSV recess will accelerate this process. By providing the fill voids, etching proceeds, at least partially, outwardly from the center fill void in the direction of the diameter of the recess, as opposed to only etching the depth of the recess. Note also, that the sacrificial material strip chemistry should not attack the CA barrier and the MOL barrier on the front-side of the wafer.

As illustrated in FIG. 2J, subsequent to sacrificial material removal from the TSV recesses, standard deposition of a diffusion barrier 262, conductive material seeding and plating, followed by CMP polishing of the conductive material back may be employed to achieve, substantially concurrently, the final through substrate via with the conductive material 260, as well as a first-level, back-side metallization layer 261. In one embodiment, the conductive material is copper. Note that using this approach filling the TSV recess with the conductive material occurs after substantially all high-temperature processing of the wafer has been completed, so that there is no likelihood of the conductive material expanding and creating stresses in the active devices during, for example, front-side processing of the wafer.

Those skilled in the art should also note that details of the process sequence and choice of materials, etc., can be varied, without departing from the scope of the invention disclosed herein. Advantageously, the TSV processing integration approach presented combines various advantages of other TSV approaches, while avoiding the shortcomings of the existing approaches. The TSV-first-and-last approach presented herein enables TSV-first processing, without limitation on the conductive fill material employed within the TSV, which enables creation of copper TSVs. Current TSV-first approaches are restricted to using silicon or tungsten as the conductive fill, which have significantly higher resistance than, for example, copper. Further, the approach disclosed herein differs from TSV-mid or TSV-last processing in that TSV-mid or TSV-last processings can impact the fabricated active devices through stress, thermal budget, etc. Further, the TSV-last process from the wafer back-side requires a difficult contact open etch, and alignment, in comparison to the approach disclosed herein.

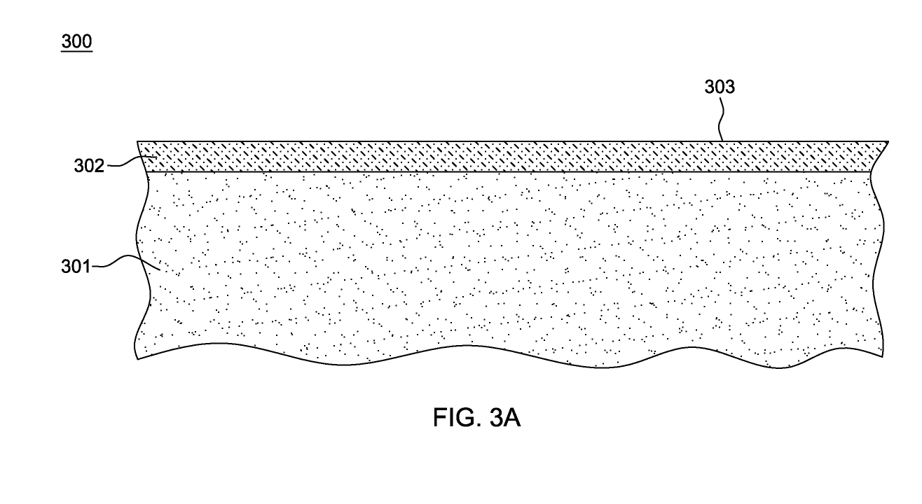

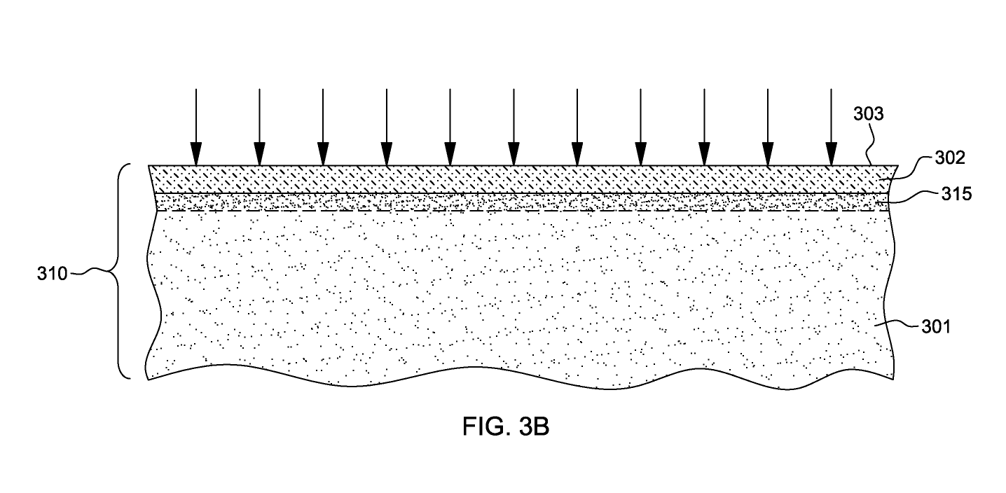

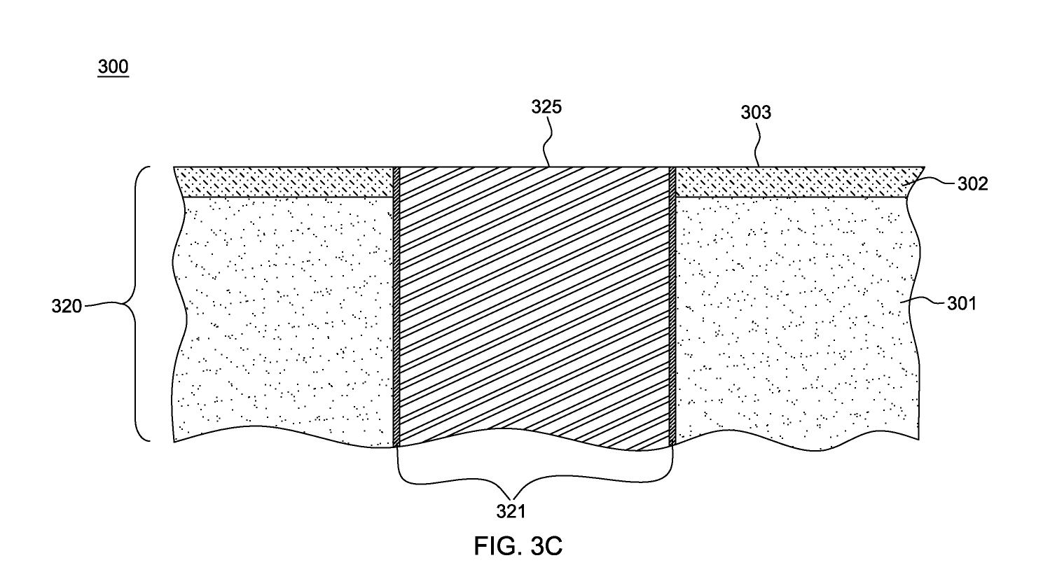

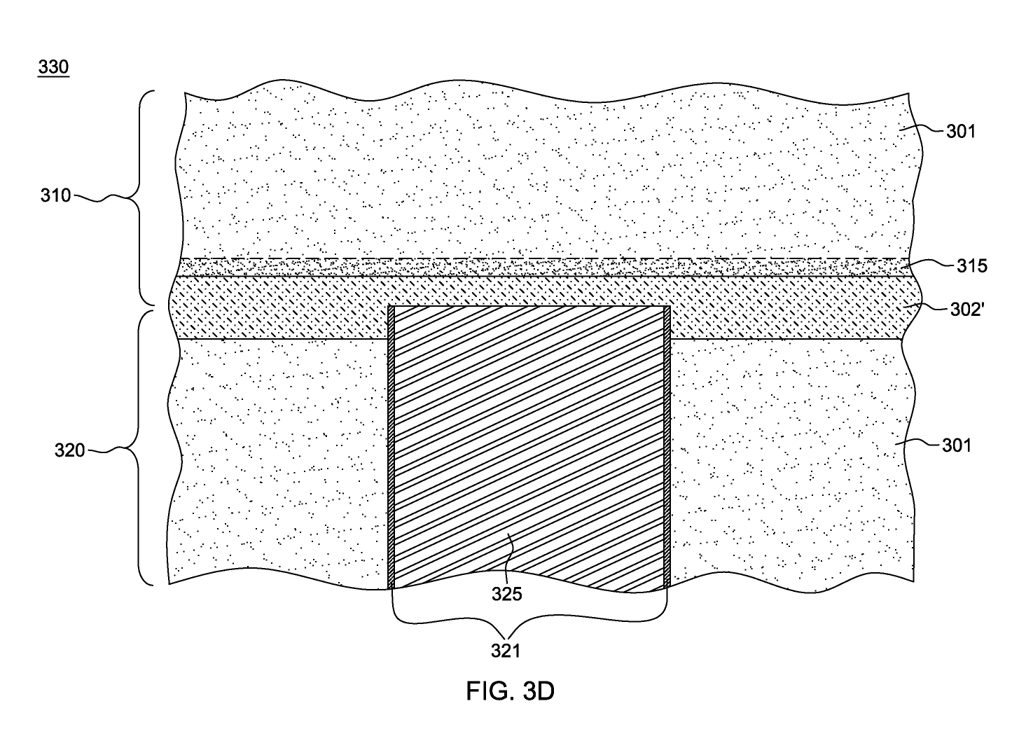

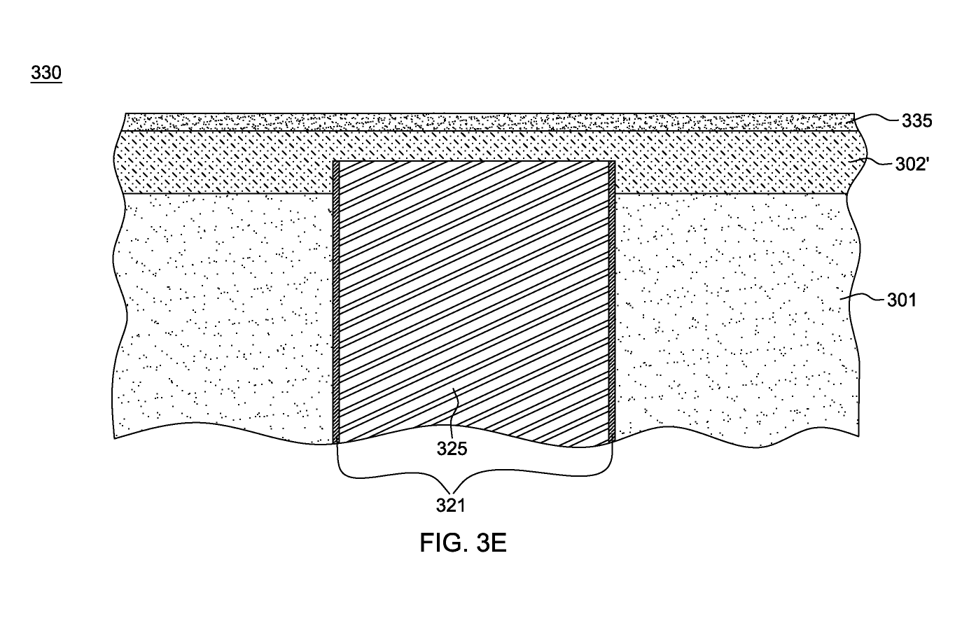

As noted, in other aspects, disclosed herein are certain novel, buried through substrate vias (TSVs), semiconductor structures incorporating the same, and fabrication approaches therefor. Various examples of these buried TSVs, semiconductor structures and fabrication approaches, which are provided by way of example only, are described below with reference to FIGS. 3A-5C. In one specific fabrication approach, the above-described TSV-first-and-last approach may be employed in forming the buried TSVs.

Existing through substrate via fabrication approaches, including the above-summarized TSV-first, TSV-mid, and TSV-last, approaches cause a disruption in the typical CMOS process flow, and consume valuable design and routing space on the semiconductor device layer (also referred to herein as the active device layer) of the semiconductor structure, which is then not available for manufacturing devices or for routing.

Generally stated, disclosed herein are semiconductor structures which comprise buried through substrate vias that address the space and processing issues noted above with respect to conventional TSV-first, TSV-mid, and TSV-last formation from the front or back side of the wafer. In particular, disclosed herein are through substrate vias that are buried, that is, are disposed within the semiconductor structure or wafer so as to terminate below the active device layer of the semiconductor structure. In this manner, buried through substrate vias do not consume valuable design space in the active device layer, and further, do not penetrate back-end-of-line (BEOL) wiring layers or levels, and thus, do not consume routing space in the BEOL wiring layers. In certain implementations, the buried TSVs may be buried at least partially in a regular array or pattern within the semiconductor structure. Alternatively, the buried TSVs may be buried at designated, irregular locations, for example, based on a particular circuit design of the resultant structure.

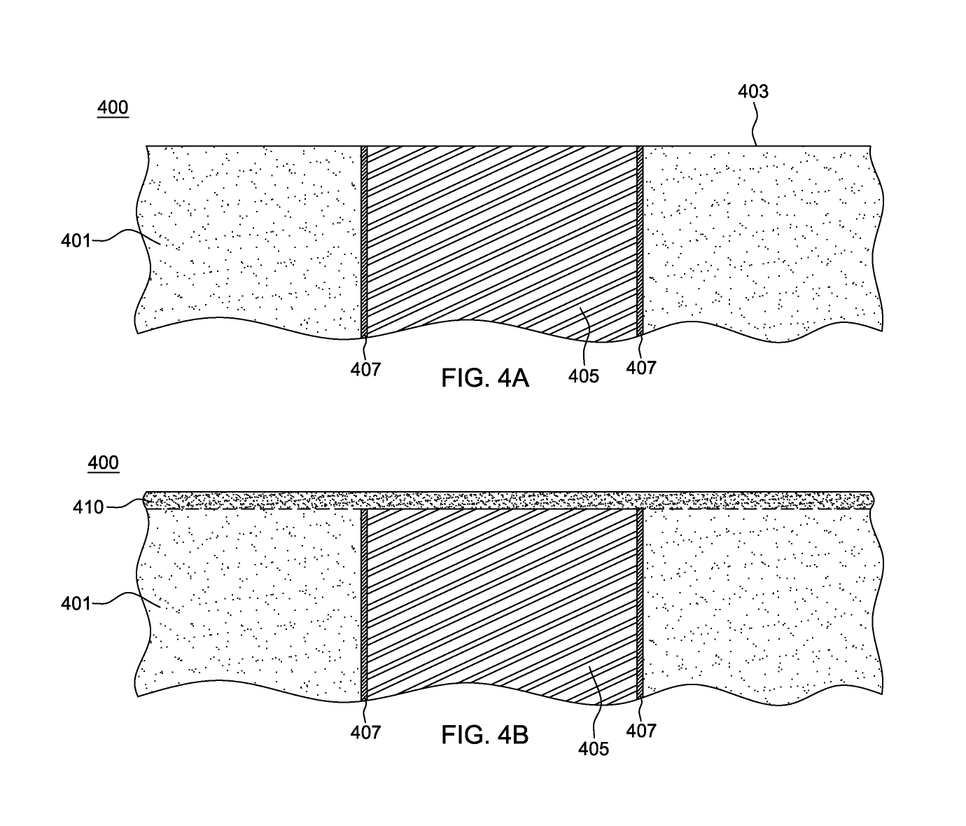

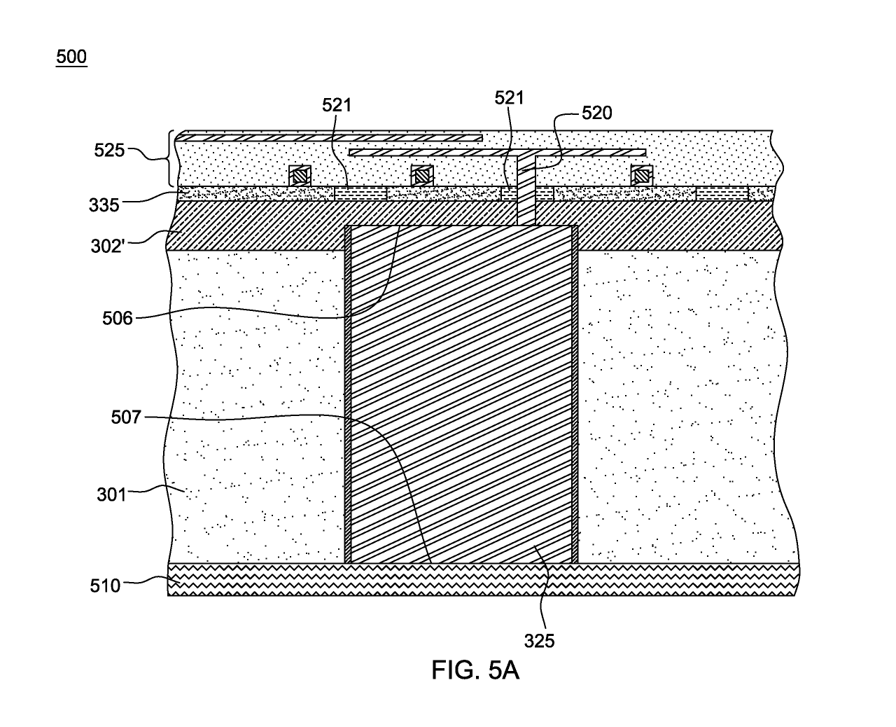

Fabrication of a buried TSV(s) includes disposing the buried TSV(s) such that the semiconductor device layer of the semiconductor structure extends above the buried TSV(s). This may be achieved, for example, by modifying a silicon-on-insulator (SOI) wafer fabrication approach, as discussed below with reference to FIGS. 3A-3E, or (for example) by employing an epitaxial growth approach over the front side of the wafer to, for example, bury the through substrate via(s) below the semiconductor device layer, as discussed below with reference to FIGS. 4A & 4B.

Beginning with the modified SOI approach depicted in FIGS. 3A-3E, FIG. 3A illustrates one embodiment of an intermediate semiconductor structure 300 (such as a wafer) comprising a substrate 301 and a dielectric layer 302 disposed, for example, at a front side of intermediate semiconductor structure 300. Substrate 301 may be of any conventional thickness using available wafer fabrication approaches, and dielectric layer 302 thickness may be selected depending, for example, on the particular application for which the resultant semiconductor structure is to be used, as described further below. In one embodiment, the dielectric layer may comprise oxide, and the substrate may comprise silicon.

Using the intermediate semiconductor structure 300 of FIG. 3A, a first semiconductor structure of FIG. 3B may be fabricated, as well as a second semiconductor structure 320 of FIG. 3C. First semiconductor structure 310 of FIG. 3B may be fabricated from the semiconductor structure of FIG. 3A by, for example, implanting hydrogen through dielectric layer 302 into substrate 301 to prepare for a subsequent semiconductor cut process. As understood in the art, such a hydrogen implant will facilitate subsequent cleaving of the non-implanted substrate 301, and thereby the providing of a thin active device layer for the resultant semiconductor structure, which is depicted by way of example in FIG. 3E. The hydrogen implant may define a semiconductor layer 315 (see FIG. 3B) that may have a thickness from a few micrometers down to, for example, 10 nanometers or less, depending on the application.

As illustrated in FIG. 3C, second semiconductor structure 320 may comprise one or more buried through substrate vias 325 extending from, for example, front side 303 through dielectric layer 302 into substrate 301 to a depth, for instance, of 30-50 μm within the substrate. Depending on the application, a plurality of buried through substrate vias 325 (isolated from substrate 301 by sidewall dielectric 321) may be provided within second semiconductor structure 320 in, for example, a regular array or pattern across at least a portion of the substrate, or may be irregularly placed within the semiconductor structure, for instance, to accommodate a particular application or design. Note further that the plurality of TSVs could comprise both a portion disposed in a regular array across at least a portion of the substrate, and a portion irregularly spaced, either within or outside of the regular array of buried TSVs. Note also that, optionally, second semiconductor structure 320 may include a barrier cap and/or additional oxide (in alternate embodiments) over the front side 303, including over the buried through substrate via(s) 325. TSVs 325 may be formed by providing appropriate via recesses (or openings) within the semiconductor structure, extending through dielectric layer 302 into substrate 301, and then filling the via recesses with a conductive material, such as copper or tungsten, chosen (for example) with reference to the thermal load of the subsequent processing. Alternatively, the via recesses could be filled with a sacrificial material (e.g., polysilicon) for later removal and fill with conductive material from the back side of the semiconductor structure, for example, using a process such as described above in connection with FIGS. 1-2J. At this point in the process, from the back side of the semiconductor structure, the buried TSVs comprising conductive material will typically be blind vias to be later exposed and finished from the back side, for example, as in existing TSV formation processes.

In FIG. 3D, first semiconductor structure 310 has been inverted and coupled to second semiconductor structure 320 by, for example, bonding the dielectric layers thereof to form a dielectric region 302′. After stacking the semiconductor structures together as depicted in FIG. 3D, the active device layer of the resultant semiconductor structure (or wafer) 330 may be exposed by removing excess substrate from the front side of the stacked structure down to, for example, the activated n-type silicon 315. This substrate removal may be accomplished (by way of example) using conventional processing techniques, such as by cleaving the substrate using a 400° C. anneal, or sideways mechanical force, or by a chemical mechanical polishing. By way of example, the resultant semiconductor device layer 335 (FIG. 3E) might have a thickness of a few micrometers down to, for example, 10 nanometers. Semiconductor structure 330 may then be employed with conventional CMOS processing, and TSV completion processing on the back side may follow, for example, as in the TSV-first or TSV-mid approaches discussed above.

FIGS. 4A & 4B depict an alternate fabrication process for producing a semiconductor structure 400 with one or more buried TSVs, as described herein. FIGS. 4A & 4B depict a non-SOI wafer implementation, wherein a substrate 401, such as bulk silicon, may have one or more buried TSVs 405 formed therein from, for example, a front surface 403 of semiconductor structure 400. A semiconductor device layer 410 may then subsequently be formed over the front side of the semiconductor structure 400 so that the buried TSV 405 terminates below the semiconductor device layer 410 and the semiconductor device layer extends over the buried TSV. In one embodiment, providing semiconductor device layer 410 may be accomplished by over-growing the buried TSV with epitaxial silicon, or by bonding, for example, a second wafer to the front side of the first semiconductor structure with the buried TSVs, and then removing excess material in a manner similar to the above-described SOI processing of FIGS. 3D & 3E. The epitaxial growth approach may be advantageous (in this implementation) from a cost standpoint.

Advantageously, the above-described buried TSV structures and fabrication approaches do not require penetration of the semiconductor device layer, nor do they require any penetration of back-end-of-line (BEOL) wiring layers above the semiconductor device layer, at least not at full width of the buried TSV. Depending on the application, the buried TSV(s) may either remain electrically isolated, for example, to facilitate heat removal or heat redistribution within the semiconductor structure, or may be electrically contacted by a second, smaller contact via for use in making electrically connection between, for example, the front side and back side of the semiconductor structure. In one embodiment, the semiconductor device layer comprises silicon that is provided above the buried TSV(s) using, for example, a modified SOI process or an epitaxial process, as described above. The choice of the TSV metal or fill material may depend on the subsequent process temperatures. Advantageously, copper may be used if the TSV is filled with a sacrificial material, which is then subsequently removed from the back side of the semiconductor structure, as described above in connection with FIGS. 1-2J.

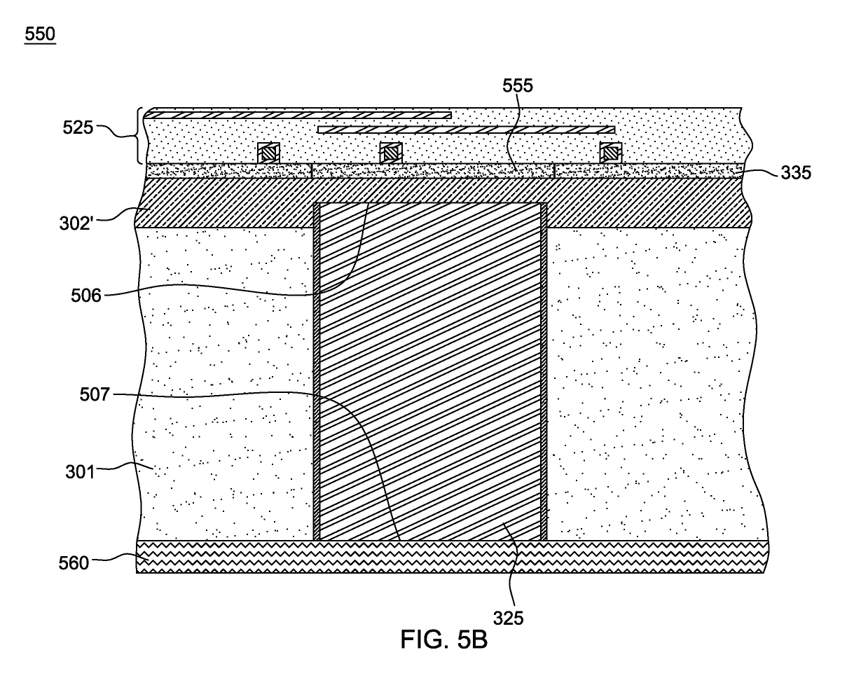

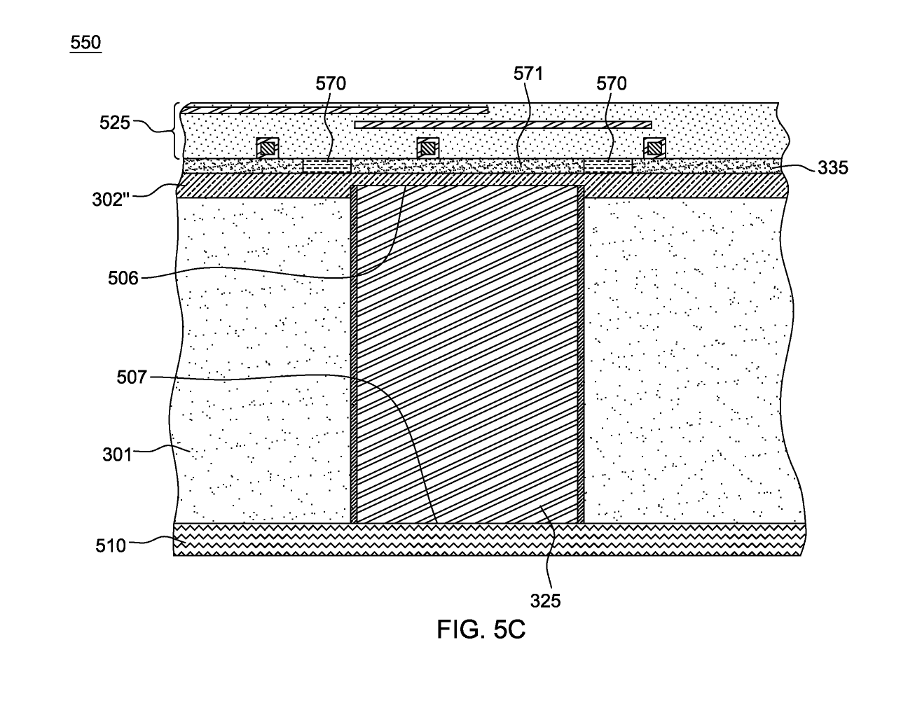

Depending on the resultant circuit, the buried TSVs may be employed in the same or in different ways within the same or different semiconductor structures. For example, as illustrated in FIG. 5A, a semiconductor structure 500 may comprise buried TSV(s) 325 within a substrate 301. The buried TSV(s) comprise a first end 506 terminating within a dielectric region 302′ and a second end 507 terminating at, for example, a back side of substrate 301, which may have one or more electrical redistribution layers 510 thereon. Electrical contact to buried through substrate via(s) 325 may be made using one or more contact vias 520 extending from or through semiconductor device layer 335 or BEOL layer(s) 525. By way of example, the device layer 335 may comprise one or more isolation regions 521, with the one or more contact vias 520 being aligned to extend through one or more isolation regions 521 in the device layer 335. This has the further advantage of not requiring dielectric inside the via to isolate the contact via from the device layer.

Advantageously, the contact via(s) 520 have a significantly smaller diameter or width compared with the diameter or width of the buried through substrate via(s) 325 to which it connects. For example, the buried through substrate via(s) 325 might be 5 microns in diameter, while the contact via(s) might have a 200-400 nm diameter using currently available technology. Thus, the contact via 520 consumes substantially less real estate of the active device layer 335, while still allowing for electrical connection from, for example, one or more BEOL layers 525 on the front side of the semiconductor structure to one or more redistribution layers 510 on the back side of the semiconductor structure. Thus, by introducing into the SOI fabrication flow, the above-described contact vias 520, for example, using processing similar to conventional contact to diffusion processing, it is possible to contact the buried TSVs for signal routing without consuming excess space on the SOI circuit, i.e., within the semiconductor device layer. For lower resistance power routing, an array of such contact vias 520 could be placed within the active device layer to contact the buried through substrate via(s) 325.

Buried through substrate vias may also be employed in a new supply chain approach. Since the buried through substrate vias disclosed herein do not consume any space on the front side (i.e., active side) of the wafer, the wafer could be provided with an at least partially repeating pattern of TSVs, so that one or more standardized sets of wafers may be provided with the same or different buried TSVs patterns. For example, one wafer type could be provided with buried TSVs in a first repeating pattern, and a second wafer type could be provided with buried TSVs in a second repeating pattern, either over the entire semiconductor structures, or only selected portions of the structures. A circuit designer could then later or separately decide which buried TSV wafer to employ for a particular purpose, and/or which buried TSVs to contact for a particular integrated circuit design. This buried TSV approach could also result in more predictable mechanical and thermal properties for the substrate, that is, as compared with an irregular placement of through substrate vias or buried through substrate vias within the structure.

FIG. 5B depicts an alternate embodiment of a semiconductor structure 550 comprising one or more buried TSVs 325 within a substrate 301, each comprising a first end 506 terminating, for example, in a dielectric region 302′. In this embodiment, the buried TSV(s) 325 is employed to remove heat locally from, for example, a designated region 555 of semiconductor device layer 335. Heat removal is fabricated (in one embodiment) by coupling second end(s) 507 of buried TSV(s) 325 to a heat sink 560 provided at the back side of the semiconductor structure 550.

In a further embodiment, the semiconductor structure 550 of FIG. 5B could be modified to facilitate controlling the floating body potential of the semiconductor structure (e.g., SOI devices) locally. In traditional SOI design this potential can only be controlled globally.

FIG. 5C depicts a further variation on the semiconductor structure of FIG. 5B, wherein, in this example, first end(s) 506 of buried TSV(s) 325 is brought closer to the semiconductor device layer 335, and in particular, to an active device region 571 within the semiconductor device layer by, for example, reducing thickness of the dielectric layer 302″ between first end 506 and semiconductor device layer 335. As illustrated, active device region 571 may be a semiconductor region within an isolation region 570, below which the buried TSV(s) 325 aligns. Then, by applying a potential from the back side to one or more of the buried TSV(s), a capacitive coupling can be achieved across the dielectric layer to the semiconductor device layer. If desired, the semiconductor device layer could itself also be modified with one or more structures to further enhance this capacitive coupling. By way of example, the active device layer may comprise a thin silicon material with MOSFETs, and the buried TSVs could be dynamically controlled from the back side of the semiconductor structure to modify the body bias for the MOSFET structures. The capacitive coupling allows for much higher frequency of switching of the body potential than currently achieved using conventional structures. For example, by creating a voltage step on the buried TSV(s), a different voltage may be induced for a short period of time within the semiconductor device layer, which may be useful, for example, in transient signal processing applications. Note further that, if desired, a high-K dielectric layer may be employed between the device layer 335 and the buried TSV(s). The particular dielectric layer chosen and its configuration would depend on the desired capacitive coupling properties of the TSV(s) to the device layer.

Advantageously, the above-described different uses of the buried TSVs may be integrated in a single semiconductor structure, that is, certain buried TSVs may be employed for heat removal or redistribution, and others used for electrically connecting between (for instance) front side metallization and back side metallization of the semiconductor structure.

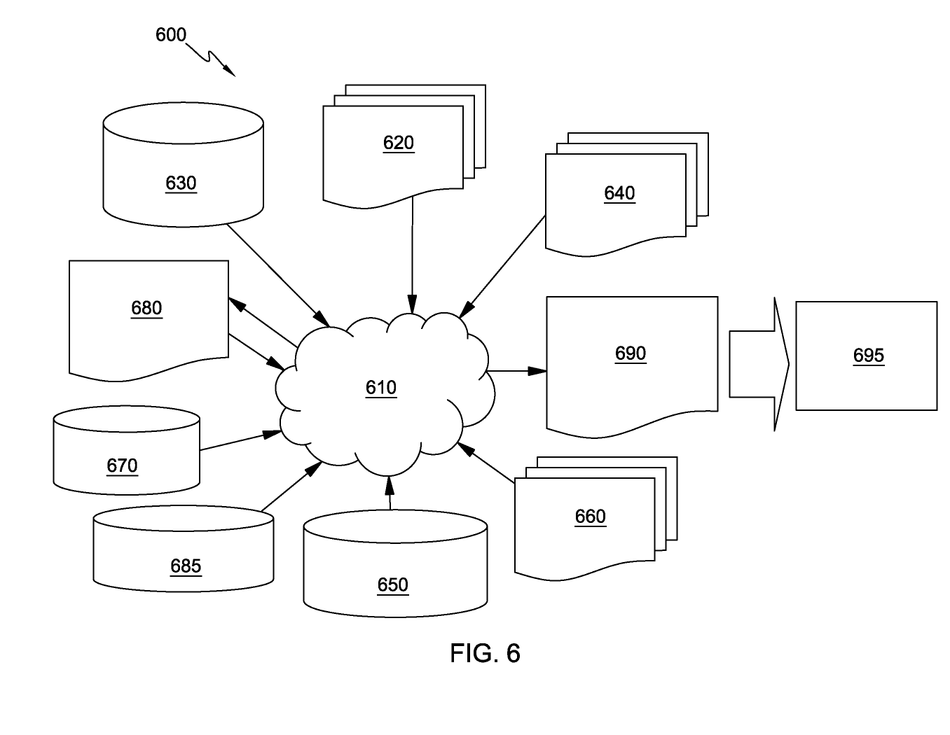

FIG. 6 depicts a block diagram of an exemplary design flow 600 used, for example, in semiconductor circuit design, simulation, test, layout, and manufacture. Design flow 600 includes processes and mechanisms for processing design structures or devices to generate logically or otherwise functionally-equivalent representations of the processes, design structures and/or devices described above and shown in FIGS. 1-5C. The design structures and/or processes generated by design flow 600 may be encoded on machine-readable transmission or storage media to include data and/or instructions that, when executed or otherwise processed on a data processing system, generate a logically, structurally, mechanically, or otherwise functionally-equivalent representation of hardware components, circuits, devices, or systems. Design flow 600 may vary, depending on the type of representation being designed. For example, a design flow for building an application specific integrated circuit (ASIC) may differ from a design flow for designing a standard component, or from a design flow for instantiating the design into a programmable array, for example, a programmable gate array (PGA) or field programmable gate array (FPGA) offered by Altera®, Inc., or Xilinx®, Inc.

FIG. 6 illustrates multiple such design structures, including an input design structure 620 that is processed by a design process 610. Design structure 620 may be a logical simulation design structure, generated and processed by design process 610 to produce a logically, equivalent-functional representation of a hardware device. Design structure 620 may also, or alternately, comprise data and/or program instruction that, when processed by design process 610, generate a functional representation of the physical structure of a hardware device. Whether representing functional and/or structural design features, design structure 620 may be generated using electronic computer-aided design (ECAD), such as implemented by a core developer/designer. When encoded on a machine-readable data transmission, gate array, or storage medium, design structure 620 may be accessed and processed by one or more hardware and/or software modules within design process 610 to simulate or otherwise functionally represent an electronic component, circuit, electronic or logic module, apparatus, device or system, such as those shown in FIGS. 1-5C. As such, design structure 620 may comprise files or other data structures, including human and/or machine-readable source code, compiled structures, and computer-executable code structures that, when processed by a design or simulation data processing system, functionally simulate or otherwise represent circuits or other levels of hardware logic design. Such data structures may include hardware-description language (HDL), design entities, or other data structures conforming to and/or compatible with lower-level HDL design languages, such as Verilog and VHDL, and/or higher-level design languages, such as C or C++.

Design process 610 may employ and incorporate hardware and/or software modules for synthesizing, translating, or otherwise processing a design/simulation functional equivalent of the components, circuits, devices or logic structures shown in FIGS. 1-5C to generate a netlist 680, which may contain design structures, such as design structure 620. Netlist 680 may comprise, for example, compiled or otherwise processed data structures representing a list of wires, discrete components, logic gates, control circuits, I/O devices, models, etc. that describes the connections to other elements and circuits in an integrated circuit design. Netlist 680 may be synthesized using an interactive process in which netlist 680 is re-synthesized one or more times, depending on design specifications and parameters for the device. As with other design structure types described herein, netlist 680 may be recorded on a machine-readable data storage medium, or programmed into a programmable gate array. The medium may be a non-volatile storage medium, such as a magnetic or optical disk drive, a programmable gate array, a compact flash, or other flash memory. Additionally, or in the alternative, the medium may be a system cache memory, buffer space, or electrically or optically conductive devices and materials on which data packets may be transmitted and intermediately stored via the Internet, or other networking suitable means.

Design process 610 may include hardware and software modules for processing a variety of input data structure types, including netlist 680. Such data structure types may reside, for example, within library elements 630 and include a set of commonly used elements, circuits, and devices, including modules, layouts, and symbolic representations, for a given manufacturing technology (e.g., different technology nodes, 32 nm, 45 nm, etc.). The data structure types may further include design specifications 640, characterization data 650, verification data 660, design rules 670, and test data files 685, which may include input test patterns, output test results, and other testing information. Design process 610 may further include, for example, standard mechanical design processes, such as stress analysis, thermal analysis, mechanical event simulation, process simulations for operations, such as casting, molding, and die press forming, etc. One of ordinary skill in the art of mechanical design can appreciate the extent of possible mechanical design tools and applications used in design process 610, without deviating from the scope and spirit of the invention. Design process 610 may also include modules for performing standard circuit design processes, such as timing analysis, verification, design rule checking, place and route operations, etc.

Design process 610 employs and incorporates logical and physical design tools, such as HDL, compilers and simulation module build tools to process design structure 620 together with some or all of the depicted supporting data structures, along with any additional mechanical design of data (if applicable), to generate a second design structure 690. Design structure 690 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 620, design structure 690 may comprise one or more files, data structures, or other computer-encoded data or instructions that reside on transmission or data storage media, and that when processed by an ECAD system, generate a logically or otherwise functionally-equivalent form of one or more of the embodiments of the invention. In one embodiment, design structure 690 may comprise a compiled, executable HDL simulation model that functionally simulates the processes and devices shown in FIGS. 1-5C.

Design structure 690 may also employ a data format used for the exchange of layout data of integrated circuits and/or symbolic data format (e.g., information stored in a GDSII (GDS2), GL1, OASIS, map files, or any other suitable format for storing such design data structures). Design structure 690 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure, such as described above and shown in FIGS. 2A-5C. Design structure 690 may then proceed to stage 695, where, for example, design structure 690 proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention.

What is claimed is:

1. A semiconductor structure comprising:
a substrate;
a semiconductor device layer supported by the substrate; and
at least one buried through substrate via (TSV) disposed at least partially within the substrate, the at least one buried through substrate via being buried within the semiconductor structure, and terminating below the semiconductor device layer of the semiconductor structure, wherein the semiconductor device layer extends over the at least one buried through substrate via.

2. The semiconductor structure of claim 1, wherein the semiconductor structure is a wafer, and the semiconductor device layer is disposed at a first side of the wafer and the substrate is disposed at a second side of the wafer.

3. The semiconductor structure of claim 2, further comprising a dielectric layer disposed between the substrate and the semiconductor device layer of the semiconductor structure, the at least one buried through substrate via terminating at a first end within the dielectric layer and terminating at a second end within the substrate.

4. The semiconductor structure of claim 3, wherein the dielectric layer comprises an oxide layer, and the semiconductor device layer comprises silicon.

5. The semiconductor structure of claim 1, wherein the semiconductor device layer comprises an epitaxially-grown layer extending over the at least one buried through substrate via.

6. The semiconductor structure of claim 1, further comprising a plurality of buried through substrate vias disposed at least partially within the substrate, the plurality of buried through substrate vias being buried within the semiconductor structure, and terminating below the semiconductor device layer of the semiconductor structure, wherein the semiconductor device layer extends over the plurality of buried through substrate vias.

7. The semiconductor structure of claim 6, wherein the plurality of buried through substrate vias are buried within the semiconductor structure in an at least partially repeating pattern across at least a portion of the semiconductor structure.

8. The semiconductor structure of claim 1, wherein the at least one buried through substrate via is spaced from the semiconductor device layer and is configured and disposed within the semiconductor structure to facilitate dissipation of heat away from a designated region of the semiconductor device layer.

9. The semiconductor structure of claim 1, further comprising a dielectric layer disposed between the substrate and the semiconductor device layer of the semiconductor structure, and wherein the dielectric layer has a thickness which spaces an end of the at least one buried through substrate from the semiconductor device layer a distance which facilitates capacitive coupling of the at least one buried through substrate via to the semiconductor device layer.

10. The semiconductor structure of claim 1, wherein the at least one buried through substrate via terminates at a first end within the semiconductor structure below the semiconductor device layer of the semiconductor structure, and is electrically contacted by at least one contact via of or extending through the semiconductor device layer, and wherein the at least one buried through substrate via has a larger diameter than the at least one contact via making electrical contact to the at least one buried through substrate via.

11. The semiconductor structure of claim 1, wherein the semiconductor structure is a wafer, and the at least one buried through substrate via buried within the wafer terminates at a first end and at a second end without reaching a first side or a second side, respectively, of the wafer, wherein the first side is a front side of the wafer and the second side is a back side of the wafer, and the front side comprises the semiconductor device layer of the wafer.

12. A method comprising:
providing a semiconductor structure comprising at least one buried through substrate via (TSV), the providing comprising:
providing a substrate;
forming the at least one buried through substrate via at least partially within the substrate; and
providing a semiconductor device layer over the at least one buried through substrate via, wherein the at least one buried through substrate via terminates below the semiconductor device layer of the semiconductor structure, and the semiconductor device layer extends over the at least one buried through substrate via.

13. The method of claim 12, wherein providing the semiconductor structure further comprises providing a dielectric layer between the substrate and the semiconductor device layer of the semiconductor structure, the at least one buried through substrate via terminating at a first end within the dielectric layer and terminating at a second end within the substrate.

14. The method of claim 12, wherein providing the semiconductor device layer further comprises epitaxially-growing the semiconductor device layer to extend over the at least one buried through substrate via.

15. The method of claim 12, wherein providing the semiconductor structure further comprises providing a plurality of buried through substrate vias disposed at least partially within the substrate, the plurality of buried through substrate vias being buried within the semiconductor structure, and terminating below the semiconductor device layer of the semiconductor structure, wherein the semiconductor device layer extends over the plurality of buried through substrate vias.

16. The method of claim 15, wherein providing the plurality of buried through substrate vias further comprises disposing the plurality of buried through substrate vias within the semiconductor structure in an at least partially repeating pattern across at least a portion of the semiconductor structure.

17. The method of claim 12, wherein providing the semiconductor structure further comprises providing a dielectric layer between the at least one buried through substrate via and the semiconductor device layer with a thickness which facilitates capacitive coupling of the at least one buried through substrate via to the semiconductor device layer.

18. The method of claim 12, further comprising configuring and disposing the at least one buried through substrate via within the semiconductor structure to facilitate dissipation of heat away from a designated region of the semiconductor device layer.

19. The method of claim 12, further comprising electrically contacting the at least one buried through substrate via using at least one contact via of or extending through the semiconductor device layer, wherein the at least one buried through substrate via has a larger diameter than the at least one contact via making electrical contact thereto.

20. A method comprising:
providing a wafer comprising at least one buried through substrate via (TSV), the providing comprising:
providing a first semiconductor structure comprising a first substrate with a first dielectric layer over the first substrate, and at least one buried through substrate via extending into the first substrate;
providing a second semiconductor structure comprising a second substrate and a second dielectric layer disposed over the second substrate;
stacking the second semiconductor structure on the first semiconductor structure and securing the first dielectric layer and the second dielectric layer together; and
thinning the second substrate of the second semiconductor structure to provide a semiconductor device layer of the wafer, wherein the at least one buried through substrate via terminates below the semiconductor device layer, and the semiconductor device layer extends over the at least one buried through substrate via.

21. A method comprising:
providing a wafer comprising at least one buried through substrate via (TSV), the providing comprising:
obtaining a substrate;
providing at least one through substrate via within the substrate; and
burying the at least one through substrate via within the substrate to define the at least one buried through substrate via, the burying comprising epitaxially growing a layer to extend over the at least one through substrate via.
